(19) United States
(12) Patent Application Publication
(10) Pub. No.: US 2022/0190044 A1
(43) Pub. Date: Jun. 16, 2022

(54) LIGHT-EMITTING APPARATUS

(71) Applicant: PERATECH HOLDCO LTD, Richmond (GB)

(72) Inventor: Apostolos Theocharis VOUTSAS, Vancouver, WA (US)

(21) Appl. No.: 17/433,144

(22) PCT Filed: Feb. 24, 2020
(86) PCT No.: PCT/GB2020/000020

§ 371 Date: Aug. 23, 2021

Related U.S. Application Data
(60) Provisional application No. 62/808,968, filed on Feb. 22, 2019.

(51) Int. Cl. H01L 27/32; H01L 51/56; H01L 51/52; G02F 1/1333; G02F 1/13357; G06F 3/044; G06F 3/041

(52) U.S. Cl. CPC H01L 27/323; H01L 51/56; H01L 51/5268; G02F 1/13338; G06F 2203/04103; G06F 3/0443; G06F 3/0412; G02F 2202/36; G06F 2203/04105; G02F 1/133606

(57) ABSTRACT

An apparatus (201) for use in a display device comprises a light-emitting layer (203) for providing a light output to the display device and a translucent layer (202) comprising a pressure-sensitive ink. The translucent layer diffuses the light output from the light-emitting layer and the pressure-sensitive ink provides a conductive layer of a sensing device (205) which is configured to measure a force in response to a mechanical interaction.

### CROSS REFERENCE TO RELATED APPLICATIONS

This application claims priority from U.S. Provisional Patent Application No. 62/808,968, filed on 22 Feb. 2019, the whole contents of which are incorporated herein by reference.

### BACKGROUND OF THE INVENTION

The present invention relates to an apparatus for use in a display device or light-emitting device, a display device and a method of manufacturing a display device.

Display devices incorporating touch screens are widely available and allow users to provide force or pressure inputs into the touch screen to affect the output from the display.

Conventional touch screens experience a problem in that they typically comprise opaque or semi-opaque layers of material which are utilized to measure the pressure input. Solutions have been proposed to provide substantially transparent inks or materials which allow for the force or pressure sensing of the touch screen to be used with the display.

Conventional display devices comprising touch screens include backlights and conductive layers which provide capacitive sensors or similar. When diffusion of light from the backlight is needed, such as in conventional LCD (liquid crystal display) devices, an additional diffusion layer is included which adds to the overall thickness and complexity of the display device.

### BRIEF SUMMARY OF THE INVENTION

According to an aspect of the present invention, there is provided an apparatus for use in a display device or light-emitting device according to claim 1.

According to a second aspect of the present invention, there is provided a method of manufacturing a display device, according to claim 14.

Embodiments of the invention will be described, by way of example only, with reference to the accompanying drawings. The detailed embodiments show the best mode known to the inventor and provide support for the invention as claimed. However, they are only exemplary and should not be used to interpret or limit the scope of the claims. Their purpose is to provide a teaching to those skilled in the art. Components and processes distinguished by ordinal phrases such as “first” and “second” do not necessarily define an order or ranking of any sort.

### BRIEF DESCRIPTION OF THE SEVERAL VIEWS OF THE DRAWINGS

FIG. 1 shows an example electronic device comprising a display and touch screen;

FIG. 2 shows an apparatus for use in a display device;

FIG. 3 shows a translucent layer for use in the apparatus of FIG. 2;

FIG. 4 shows a cross sectional view of the apparatus of FIG. 2 incorporated into a display device;

FIG. 5 shows an example display device incorporating an apparatus of the present invention;

FIG. 6 shows a further example display device incorporating an apparatus of the present invention;

FIG. 7 shows a still further example display device incorporating an apparatus of the present invention;

FIG. 8 shows a further embodiment in accordance with the invention comprising an OLED;

FIG. 9 shows a light-emitting device in the form of a light fixture; and

FIG. 10 shows the light-emitting device of FIG. 9 in operation.

### DETAILED DESCRIPTION OF EMBODIMENTS OF THE INVENTION

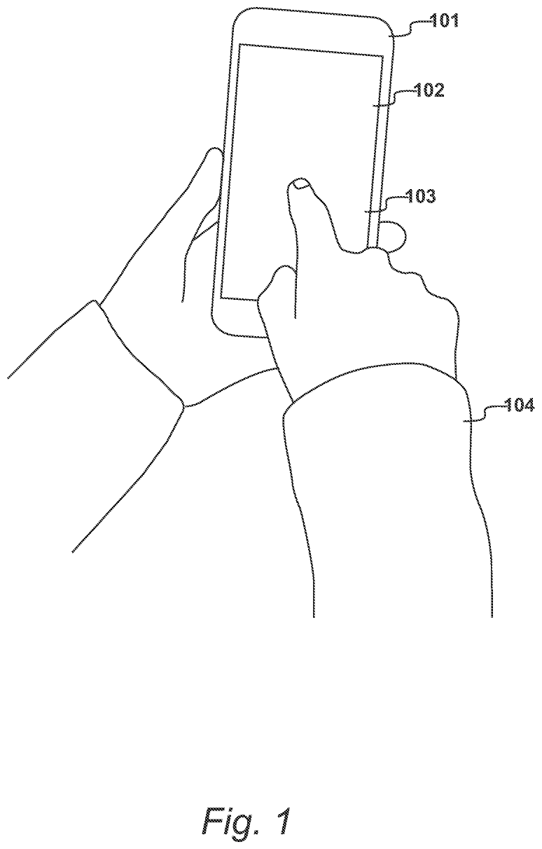

### FIG. 1

An example electronic device comprising a display and touch screen is shown in FIG. 1. Electronic device 101 comprises a touch screen 102 which incorporates a display 103. In the embodiment, electronic device 101 is a mobile telephone, however, it is appreciated that, in alternative embodiments, other electronic devices comprising touch screens and displays may be utilized. This includes, but is not limited to, personal computers, tablet computers, audio and/or visual players or other media players or other electronic devices.

In the embodiment, a user 104 provides an input to touch screen 102 to electronic device 101 by means of a finger press which may control an output onto display 103. It is appreciated that, as an alternative to the finger press illustrated in FIG. 1, other mechanical interactions may be provided, such as an input from an input device, for example, by means of a stylus, or other applications of force or pressure to touch screen 103.

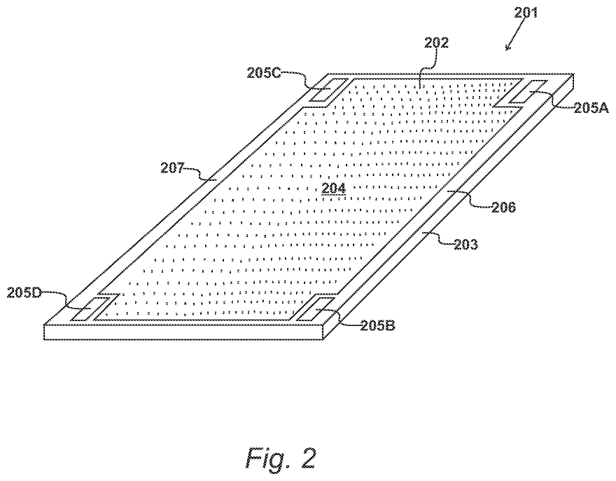

### FIG. 2

An example apparatus for use in a display device such as the electronic device 101 shown in FIG. 1 is shown in FIG. 2. Apparatus 201 is shown in perspective view and is suitable for use in a display device comprising the apparatus.

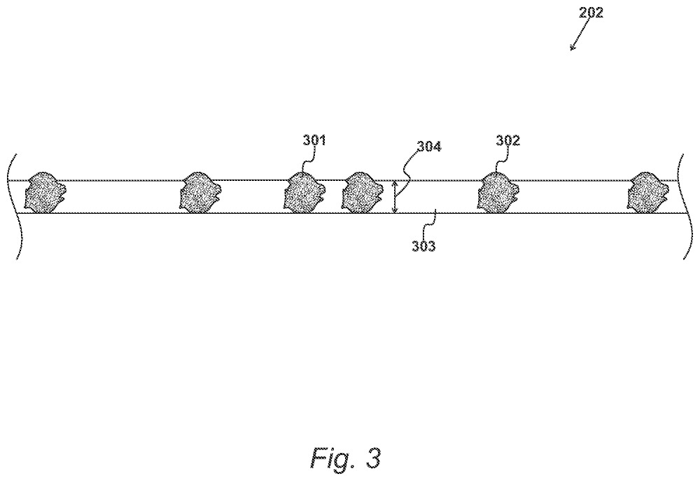

Apparatus 201 comprises a translucent layer 202 which overlays a light-emitting layer 203. Translucent layer 202 comprises a pressure-sensitive ink which will be described in further detail with respect to FIG. 3.

In the embodiment, apparatus 201 comprises a first area 204 configured to diffuse light output from a display device and a second area 205 which is configured to measure a force or pressure in response to a mechanical interaction.

In the embodiment, the apparatus comprises a rectangular or square cross section as shown and the second area 205 is arranged as individual elements (205A, 205B, 205C and 205D) in each corner of the rectangular cross section. In an alternative embodiment, the second area is arranged around the edge of the apparatus, such as along edge 206 or 207. In a specific embodiment, the second area may extend around the entire perimeter of first area 204 so as to provide an area which can measure a force or pressure in response to a mechanical interaction surrounding an area configured to diffuse the light output from apparatus 201.

In each embodiment, the second area is arranged to form a sensing device such that, each of the corners can be used to measure a force in response to a finger press or similar.

### FIG. 3

An example embodiment of translucent layer 202 is shown in FIG. 3. Translucent layer 202 comprises a pressure-sensitive ink which is responsive to a change in force or pressure applied to the translucent layer. The pressure-sensitive ink is an active sensing ink which allows light to be passed through it unlike conventional materials which are typically substantially opaque.

In the embodiment, translucent layer 202 comprises a plurality of agglomerates, such as agglomerates 301 and 302, which in turn comprise a plurality of conductive or semi-conductive particles. The plurality of agglomerates (301, 302) are arranged into a carrier layer 303 which comprises a solidified polymeric material.

In an embodiment, the carrier layer 303 comprises any suitable liquid carrier which comprises a component capable of solidifying to produce a solidified polymeric material. In order to produce the composite material, the agglomerates are introduced into the liquid carrier and mixed to disperse the agglomerates within the liquid carrier before solidification takes place.

The resultant carrier layer 303 has a length and a width and a thickness 304 which is relatively small compared to the width. In the embodiment, the thickness 304 is between four and six micrometers (4-6 μm).

The plurality of agglomerates (301, 302) have a largest dimension of between four and twenty micrometers (4-20 μm), but in the embodiment, the largest dimension is typically between four and ten micrometers (4-10 μm). In particular, the thickness 304 of carrier layer 303 is smaller than the largest dimension of each agglomerate. For example, the agglomerates have a largest dimension of between eight and ten micrometers (8-10 μm) for a carrier layer thickness of six micrometers (6 μm). Thus, in this way, the agglomerates protrude slightly from the solidified carrier layer 303 so that they are able to provide a conductive path when a pressure is applied.

In this way, translucent layer 202 can be utilized as a conductive layer in a sensing device in accordance with the present invention.

In addition, by ensuring the liquid carrier forming the carrier layer 303 is sufficiently translucent in nature, and that the agglomerates are sufficiently spaced, a substantially translucent layer can be obtained which is also conductive.

In the embodiment, the translucent layer comprises only semi-conductive or conductive particles and does not contain inert particles which reduce the transparency of the layer. In a further embodiment, the pressure-sensitive ink is a uv-cured ink which further does not include inert particles and further enhances the transparency of the translucent layer 202.

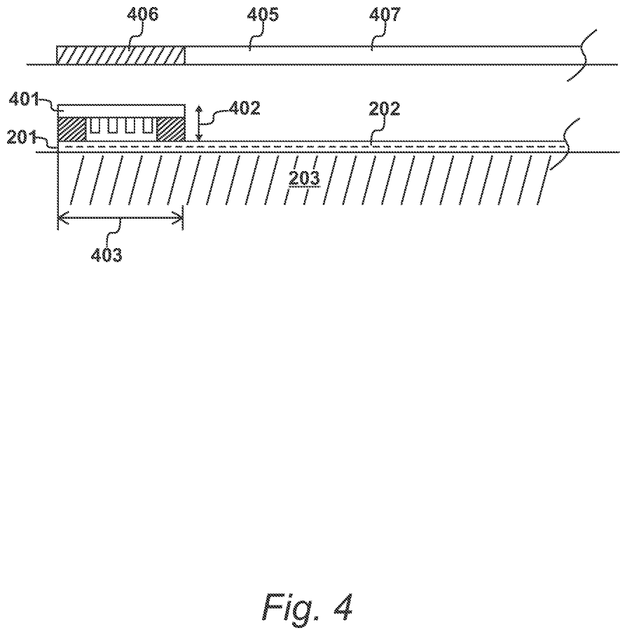

### FIG. 4

Part of one of the corners of apparatus 201 is shown in FIG. 4 in cross section exploded view showing the translucent layer 202 and light-emitting layer 203.

Apparatus 201 includes light-emitting layer 203 which provides a light output to a display device into which apparatus 201 is incorporated. Apparatus 201 further comprises translucent layer 202 as previously described which comprises a pressure-sensitive ink which provides a conductive layer which forms part of a sensing device which is configured to measure a force in response to a mechanical interaction. Sensing device 401 therefore comprises translucent (conductive) layer 202 onto which further conductive layers are included to form sensing device 401. In a typical arrangement, translucent layer 202 and further conductive layers are arranged to present a matrix of conductive rows and columns from which a position and extent property may be determined in response to a force or pressure applied. In an embodiment, the total height 402 of sensing device 401 is between one hundred and one hundred and fifty micrometers (100-150 μm). In a particular embodiment, the height 402 is one hundred micrometers (100 μm). The sensing device 401 is kept at a minimal height in order to ensure that the display device can be made as thin as possible and such that the sensing device has a limited impact on the outer dimensions of the display device or electronic device into which the display is incorporated.

In an embodiment, the width 403 of sensing device 401 is less than one millimeter (1 mm). A display device further comprises a top cover 405, as shown in exploded view to apparatus 201, and, in this illustrated embodiment, an edge portion 406 of top cover 405 is configured to cover the sensing device 401. A further portion 407 of the display device covers translucent layer 202 and portion 407 comprises a further transparent area which, allows light output from light-emitting layer 203 to be transmitted from light-emitting layer 203, through translucent layer 202 and through transparent portion 407, having been diffused by means of translucent layer 202.

In this way, a user can utilize sensing device 401 to provide an input into the display device by applying a force or pressure to the edge of the display device where sensing device 401 is positioned, while the translucent layer underneath the transparent portion 407 can be used to diffuse light output from the light-emitting layer 203, such as a backlight, without requiring a further layer to be introduced that would not already be present in the sensing device.

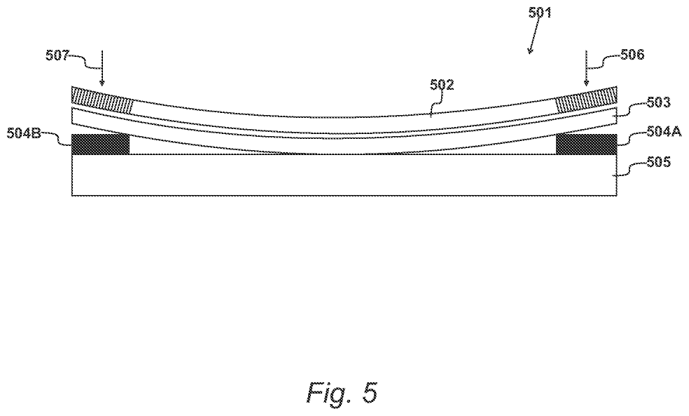

### FIG. 5

An example display device 501 shown in diagrammatic cross-sectional view is shown in FIG. 5. Display device 501 comprises a cover 502, an LCD (liquid crystal display) layer 503, at least one sensing device 504 and a light-emitting layer 505.

In the embodiment, a force can be applied as illustrated by arrows 506 and 507 to activate sensing device 504 which is positioned around the edge or corners of display device 501. In this way, the display and light from the light-emitting layer can be transmitted through the substantially translucent portions of the cover 502 as described in FIG. 4.

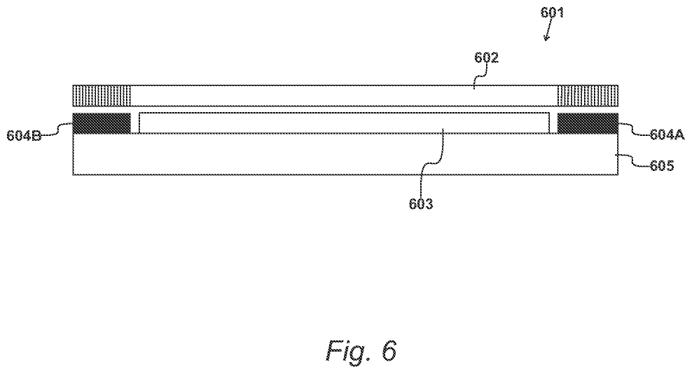

### FIG. 6

A further example display device 601 is shown in FIG. 6, again in diagrammatic cross-sectional view. In this illustrated embodiment, display device 601 again comprises a cover 602, an LCD (liquid crystal display) layer 603, at least one sensing device 604 and a light-emitting layer 605.

In this embodiment, the LCD layer is positioned between the outer sensing devices 604 and under the substantially translucent portion of the top cover 602. In this way, a relatively thin arrangement is achieved that further maintains the layers in their orientation with reduced warping or bending.

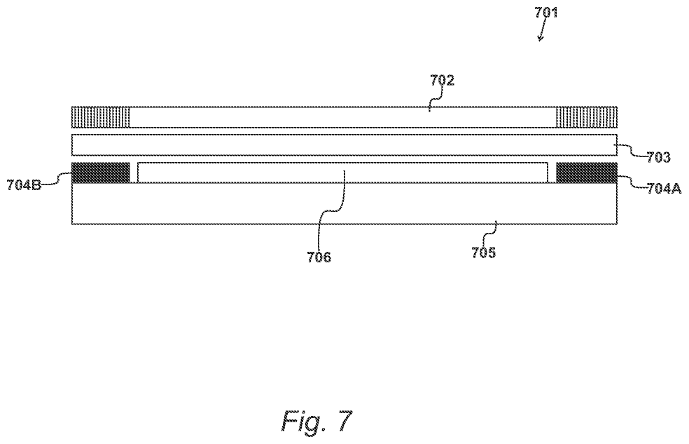

### FIG. 7

A still further example display device 701 is shown in FIG. 7, again in diagrammatic cross-sectional view. In this illustrated embodiment, display device 701 again comprises a cover 702, an LCD (liquid crystal display) layer 703, at least one sensing device 704 and a light-emitting layer 705.

In addition, in the embodiment, display device 701 further comprises an adhesive layer 706 comprising, in this case, an index-matched OCA (optically clear adhesive) to planarize the sensor.

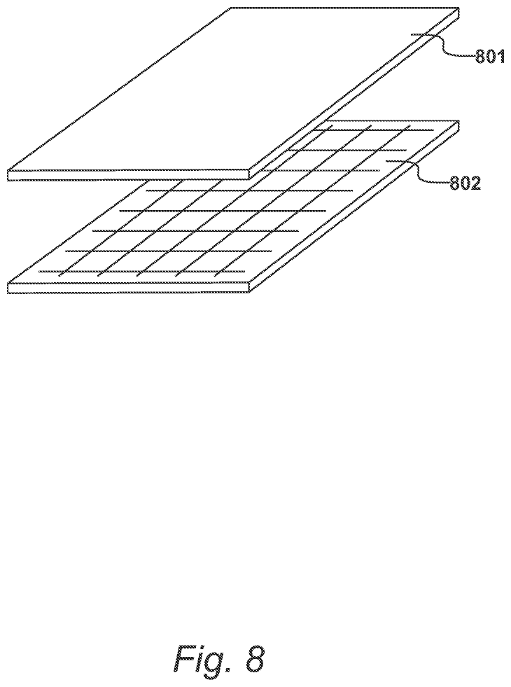

### FIG. 8

The apparatus herein is also suitable for application with light-emitting devices such as light fixtures which use organic light emitting diodes (OLEDs). A translucent layer as described herein, such as translucent layer 202, can be utilized as an input surface in combination with the OLED.

FIG. 8 shows an exploded view illustrating an embodiment of this type. Translucent layer 801 is substantially similar to the embodiments of translucent layer 202 described previously. In particular, translucent layer 801 comprises a pressure-sensitive ink which comprises a quantum tunnelling material such as that provided by the present applicant, Peratech Holdco Limited under the trade name QTC®. The pressure sensitive ink therefore comprises a plurality of conductive or semi-conductive particles. In an embodiment, the pressure-sensitive ink comprises a uv-cured ink.

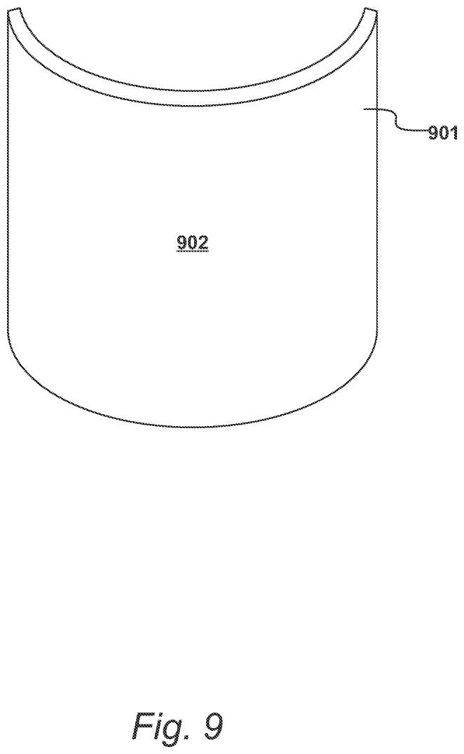

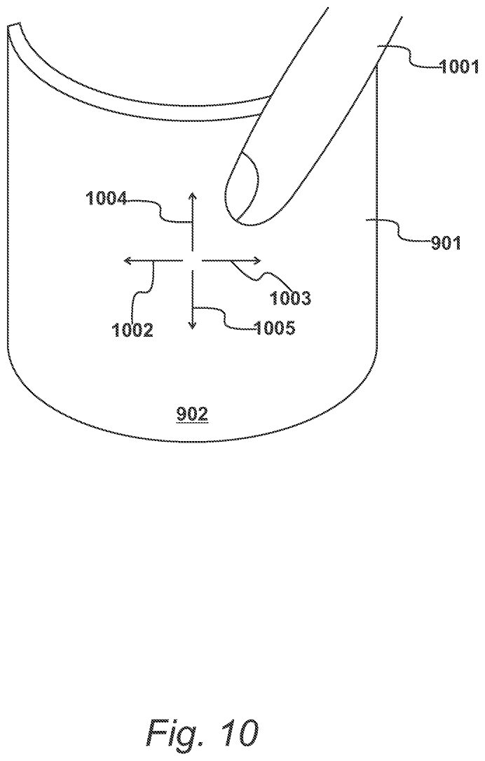

In the embodiment, a light-emitting layer 802 is also provided, however, in this embodiment, light-emitting layer 802 comprises an organic light emitting diode in sheet form. When combined together, the OLED layer forms a layer of a sensing device, as will be described with respect to FIGS. 9 and 10.

### FIG. 9

Translucent layer 801 and light-emitting layer 802 comprising an OLED are shown combined in FIG. 9. In this embodiment, apparatus 901 provides an input surface 902 formed from translucent layer 801 positioned over light-emitting layer 802, which provides a light output through translucent layer 801. Translucent layer 801 therefore provides diffusion of light as well as pressure sensing functionality to apparatus 901.

In the embodiment, apparatus 901 comprises a curved light fixture, however, it is appreciated that apparatus 901 may further comprise other electronic devices including display devices as described previously.

### FIG. 10

Apparatus 901 provides an input surface 902 as described previously. Due to the sensing capacity of translucent layer 801, a user 1001 can press onto input surface 902 enabling a force to be measured in response to the mechanical interaction, in this case the user's press. In this way, apparatus 901 can be switched on or off or adjusted accordingly.

For example, user 1001 can input a gesture in the form of a swipe to change the intensity of the light emitted from apparatus 901. This can be achieved by swiping left or right for example in the direction of arrows 1002 or 1003 respectively. In addition, user 1001 may swipe up or down, for example, in the direction of arrows 1004 or 1005 respectively to change the characteristics of the light. This can include altering the intensity or changing the color output to an alternative color. In this way, the translucent layer can be utilized as both an input device or a diffuser. This means that there is no longer a need to include additional switches or buttons on the LED fixtures.

1. Apparatus for use in a display device or light-emitting device, comprising:
a light-emitting layer for providing a light output; and
a translucent layer comprising a pressure-sensitive ink; wherein:
said translucent layer is arranged on top of said light-emitting layer such that said translucent layer is configured to diffuse said light output from said light-emitting layer; and
said pressure-sensitive ink provides a conductive layer of a sensing device configured to measure a force in response to a mechanical interaction.

2. Apparatus according to claim 1, wherein said pressure-sensitive ink comprises a quantum tunnelling composite material.

3. Apparatus according to claim 1, wherein said pressure-sensitive ink comprises a plurality of conductive or semi-conductive particles.

4. Apparatus according to claim 1, wherein said pressure-sensitive ink comprises an ultraviolet-cured (uv-cured) ink.

5. Apparatus according to claim 1, wherein said apparatus comprises a first area for diffusing said light output and a second area for measuring said force in response to said mechanical interaction.

6. Apparatus according to claim 5, wherein said second area is arranged around an edge of said apparatus.

7. Apparatus according to claim 5, wherein said apparatus comprises a rectangular or square cross section and said second area is arranged as elements in each corner of said rectangular or square cross section.

8. Apparatus according to claim 1, wherein said light-emitting layer comprises an organic light-emitting diode (OLED).

9. Apparatus according to claim 8, wherein said OLED forms a further layer of said sensing device.

10. Apparatus according to claim 8, wherein said translucent layer forms an input surface.

11. Apparatus according to claim 10, wherein said input surface is configured to adjust said light output from said light-emitting layer.

12. Apparatus according to claim 1, further comprising an index-matched optically clear adhesive.

13. A display device comprising a touch screen and a sensing device and the apparatus of claim 1.

14. A method of manufacturing an apparatus for use in a display device, comprising the steps of:
providing a light-emitting layer for providing a light output;
printing a pressure-sensitive ink to form a translucent layer on top of said light-emitting layer and configuring said translucent layer to diffuse said light output; and
constructing a sensing device comprising a conductive layer provided by said pressure-sensitive ink and configuring said sensing device to measure a force in response to a mechanical interaction.

15. A method of manufacturing according to claim 14, further comprising the step of:
arranging said display device to comprise a first area for diffusing said light output and a second area for measuring said-a force in response to said-a mechanical interaction.

16. A method of manufacturing according to claim 15, wherein said step of arranging comprises arranging said second area around an edge of said display device.

17. A method of manufacturing according to claim 15, wherein said display device comprises a rectangular or square cross section and said step of arranging comprises arranging said second area as a plurality of elements in each corner of said rectangular or square cross section.

18. A method of manufacturing according to claim 14, wherein said light-emitting layer comprises an organic light-emitting diode (OLED), and said method further comprises forming a further layer of said sensing device by means of said OLED.
